(19) United States
(12) Patent Application Publication
(10) Pub. No.: US 2007/0176685 A1
(43) Pub. Date: Aug. 2, 2007

(54) Extremely low noise V-band amplifier

(76) Inventor: Arlen Barksdale, Lake City, CO (US)

Correspondence Address: GARY L. EASTMAN, EASTMAN & ASSOCIATES, 707 BROADWAY STREET, SUITE 1800, SAN DIEGO, CA, 92101, US

(21) Appl. No.: 10/884,626

(22) Filed: Jul. 2, 2004

Related U.S. Application Data
(60) Provisional application No. 60/485,031, filed on Jul. 2, 2003.

(51) Int. Cl. H03F 3/04

(52) U.S. Cl. 330/289

(57) ABSTRACT

A high-performance Peltier-cooled single-channel millimeter-wave low-noise amplifier (LNA) capable of operating over an on-orbit operating temperature range of −40° C. to +80° C. with a noise figure on the order of 1.5 dB.

### BACKGROUND

Recent strides based on a reliable GaAs PHEMT process, millimeter-wave components have been reliably produced for frequencies of 23, 26, and 38 GHz designed for line of sight communications applications [7] as well as single-ended HEMT technology in the 55-65 GHz range. MMIC amplifiers were first developed as convenient gain blocks for circuits requiring a boost in signal level. Although MMIC amplifiers may contain several transistor stages and impedance-matching circuits, most still require a considerable number of supporting external components for proper operation [8]. However noise levels at ambient temperatures has not been improved much beyond 2.5 dB [9].

### TECHNICAL APPROACH GOAL

Develop a high performance prototype of a millimeter-wave rating over an on-orbit operating temperature range of −40° C. to +80° C. with a noise figure on the order of 1.5 dB.

Typical gains at 42 Ghz are shown in Graph 1 at ambient temperature:

[image]

As shown in Table 1, the broadband noise figure at room temperature (296° K.) is expected to bracket approximately 1.8 to 2.8 dB over the sample used:

TABLE 1

| Frequency | Gain (dB) @ | Noise Figure (dB) | Noise |
|---|---|---|---|
| (GHz) | 23° C. | @ 23° C. | Temperature °K |
| 26 | 34.5 | 2 | 50 |
| 30 | 33.5 | 1.8 | 45 |
| 35 | 32 | 1.8 | 45 |
| 40 | 30.5 | 2.8 | 70 |

The noise figure of the Low-Noise Amplifier (LNA) is sensitive to temperature and will improve noise level performance upon cooling. The noise curves as a function of temperature generally be can be computed from
NT₂/NT₁=(T₂/T₁)^{1.8}
where NT₂=Noise Temperature at T₂
NT₁=Noise Temperature at T₁ (given at 296° K.)
T₂=Temperature 2 in ° K.
T₁=Temperature 1 in ° K. (given as 296° K.)

A reasonably good V-band preamp may have a 70° K. noise temp at room ambient temperature (see Table 1) so a 100° K. reduction in temperature would lower preamp noise by a factor of 0.48. Obviously then a temperature delta of only approximately 100° will achieve a noise figure reduction in the neighborhood of 1.4 dB—see Table 2.

TABLE 2

| Frequency | Noise Figure (dB) | Noise |
|---|---|---|
| (GHz) | @ 196° K | Temperature °K |
| 26 | 0.95 | 23.8 |
| 30 | 0.86 | 21.4 |
| 35 | 0.86 | 21.4 |
| 40 | 1.33 | 33.3 |

Commercially LNA products are available in the higher band arena (55 to 65 GHz) that uses 0.1 mm HEMT technology to achieve 3.5 to 4.5 dB noise figures. This single ended MMIC has four stages packed into a small 1.3 sq. mm area with a gain across the frequency band of>20dB.

Now comparing room temperature (Table 1) vs. a 100 degree cooling (Table 2) yields the results shown in Graph 2 for the sample 26-40 GHz range:

[image]

A corresponding result is expected in the 40 to 60 GHz range as well. To effect cooling options one can look to cryogenics which are indeed effective but bulky, unwieldy and require replenishment which is difficult in orbit. Other cooling options also have come into use—amateur astronomers [10] have successfully employed solid-state Peltier Effect thermoelectric cooling devices [11] to lower the ambient temperature of their preamplifiers. Commercial TE modules are available readily providing a delta T of 100°. Three stage devices can drop the temperature another 20° and four stage devices begin to push the limit at 130° delta. Following the example above, we believe a low cost, effective solution for V-band can be effected through the utilization of proven off-the-shelf V-band LNA devices synergistically coupled with low cost thermoelectric coolers. For practical purposes in size matching and power consumption on an orbital platform, we will target a 2 stage device maximum, typically 1.1 amp at 3.6 volts with a convenient size match to our LNA configuration. Existing LNA suppliers in the 26-40 GHz and the 55-65 GHz ranges can provide spectrum end samples of devices in the 40-55 GHz band. Both 1 and 2 stage Peltier coolers are readily available off-the-shelf in the size configuration required to complete the total design package.

Commercialization Strategy

The principal commercialization potential of the suggested device (LNA) is its ability to provide extremely low noise, high sensitivity microwave frequency detection. This is useful in specialty radars and communication systems, both military and commercial as well as line-of-sight radio. There is a developing need for satellite communications at this frequency. Due to spectrum limitations at the lower bands, both commercial and military satellites can be expected to utilize the millimeter wave bands once the technology becomes available to transmit and receive at these frequencies. Typical high yield information in specialty radars would be useful in detecting small signature reflections from stealth enabled objects, sea, air or land. The high sensitivity would open up the ability to obtain significant new information regarding the physical sources of surface and on-surface movements [4]; e.g. volcanic magma movement, earth slides, avalanches, tsunami, earthquake induced ground movement, etc.

### REFERENCES

[1] Gray and Meyer, Analysis and Design of Analog Integrated Circuits, John Wiley and Sons, Inc., New York, N.Y., 1977.
[2] Daniel, Luca, Terrovitis, Manolis, “A Broadband Low-Noise-Amplifier”, May 1999, Department of Electrical Engineering and Computer Sciences, University of California, Berkeley.
[3] Guillermo Gonzalez, Microwave Transistor Amplifiers—Analysis and Design, Prentice-Hall, Inc., Englewood Cliffs, N.J., 1984. [2] Carson, R. S. “High Frequency Amplifiers”, 1982, Wiley.
[4] A. K. Arakelian, “Simultaneous Doppler-Radar and Dual-Polarization Radiometer Sensing in Environmental Investigations”, Turkish J. of Physics, vol. 20, no. 8, 1996, pp. 862-868.
[5] Gonzales, Guillermo, “Microwave Transistor Amplifiers—Analysis and Design”, Prentice-Hall, 1984.
[6] Battaglia, “Design A Low-Noise Communications Amplifier”, Microwaves and RF, December 1999. www.planetee.com/planetee/servlet/DisplayDocumentArticleID=9126.
[7] J. Browne, “Radio Chip Set Power Millimeter-Wave Systems”, Microwaves and RF, June 2001, p. 131.
[8] Mini-Circuits Engineering Department, “MMIC Amps Add Gain and Isolation”, Microwaves and RF, April 2002, p. 86.
[9] Palmer et al., “Suitable Receiver Technology at 40 GHz”, Phillips Broadband Presentation, Lillehammer, March 1999.
[10] SETI League website, “Cooling Low Noise Amplifiers”, last updated Jun. 6, 1998, http://www.setileague.org/mainmenu.htm
[11] Norm Dye and Helge Granberg, Radio Frequency Transistors Principles and Practical Applications, Butterworth-Heinmann, Boston, Mass., 1993.
[12] L. I. Anatychuk, “Thermoelements and Thermoelectrical Devices”, RMT Ltd, Kiev, 1979, p. 151.
   Keywords:

Amplifier, Noise Figure, Broadband, Gain, MMIC, Millimeter Wave, LNA, Peltier Cooled Microwave Detectors.

I claim:

1. An extremely low noise V-band amplifier, comprising:
a low noise amplifier operable in the v-band;
a means for cooling said amplifier in contact with said low noise amplifier; and
a control device in communication with said means for cooling wherein said control device provides a control signal to said means for cooling to adjust the temperature of said low noise amplifier.
